(19) United States
(12) Patent Application Publication
(10) Pub. No.: US 2021/0335921 A1
(43) Pub. Date: Oct. 28, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO,, LTD., Wuhan (CN)

(72) Inventor: Weibin ZHANG, Wuhan (CN)

(73) Assignee: WUHAN CHINA STAR OPTOELECTRONICS SEMICONDUCTOR DISPLAY TECHNOLOGY CO,, LTD., Wuhan (CN)

(21) Appl. No.: 16/475,378

(22) PCT Filed: Apr. 12, 2019
(86) PCT No.: PCT/CN2019/082453

§ 371 Date: Jul. 2, 2019

(30) Foreign Application Priority Data
Dec. 14, 2018 (CN) 201811536561.8

(51) Int. Cl. H01L 27/32

(52) U.S. Cl. CPC H01L 27/3244; H01L 2227/323

(57) ABSTRACT

Provided herein are a display panel and a manufacturing method thereof. The display panel is formed by integrating an anode and a drain electrode to avoid the contact resistance between the anode and the drain electrode, thereby skipping a metal annealing process. Moreover, the anode is formed by using zinc oxide which is superior to ITO in resistance and light transmittance and is easy to be subsequently etched, thereby reducing the turn-on resistance of the display panel and increasing light reflection by the anode.

### FIELD OF INVENTION

The present invention generally relates to the display technology and, more particularly, to a display panel and a manufacturing method thereof.

### BACKGROUND OF INVENTION

Flat-panel displays (FPDs) such as the liquid crystal display (LCD) and the organic light-emitting diode (OLED) display have gradually replaced the cathode-ray tube (CRT) display. Among them, the OLED display has many advantages such as self-luminescence, low driving voltage, high luminescent efficiency, short response time, high definition and contrast, near 180° viewing angle, wide temperature range, the feasibility of flexible and large-area full-color display, and has thus become the most promising display device.

An OLED display panel is an important part of an OLED display. As shown in FIG. 1, an OLED display panel generally includes: a base substrate (including a polyimide (PI) film layer 11, a barrier layer 12, a buffer layer 13), and a plurality of thin-film transistors disposed and arranged in an array on the base substrate. Each of the thin-film transistors includes a semiconductor layer 14, gate insulating layers 15, 17, gate electrodes 16, 18, interlayer dielectric layers 19, 23, a source electrode 15, a drain electrode 22, an anode, an organic material layer (not shown), and a cathode. The source electrode 15 and the drain electrode 22 contact both sides of the semiconductor layer 14, respectively. The anode 27 is disposed on the thin-film transistor and contacts the drain electrode 22 of the thin-film transistor. The organic material layer (not shown) is disposed on the anode 27 and specifically includes a hole injection layer (HIL), a hole transport layer (HTL), an organic emitting layer (EML), an electron transport layer (ETL), and an electron injection layer (EIL). The cathode 27 is disposed on the organic material layer. The thin-film transistor is covered with a planarization layer 24 thereon. The anode 27 is disposed on the planarization layer 24 and contacts the drain electrode 22 of the thin-film transistor through a via penetrating the planarization layer 24. The source electrode 15 and the drain electrode 22 of the thin-film transistor contact both sides of the semiconductor layer 14 of the thin-film transistor, respectively. The contact of the source electrode 15 with the semiconductor layer 14 and the contact of the drain electrode 22 with the semiconductor layer 14 are both metal-semiconductor contacts. In addition, a pixel defining layer 28 and a spacer layer 29 are further laminated on the organic material layer. In the bending region, the metal trace layer 21 is disposed on the interlayer dielectric layer 23.

The display principle of an OLED display is that, under a certain driving voltage, electrons and holes are injected to the electron transport layer and the hole transport layer from the cathode and the anode, respectively, and then migrate through the electron transport layer and the hole transport layer to recombine in the organic emitting layer and form excitons, which are decayed to emit visible light through radiation relaxation, as shown in FIG. 2.

The OLED display is a current-controlled light-emitting device, and the current intensity directly affects the light intensity. Therefore, the electrical requirements for thin-film transistors are crucial. According to the research by scholars, the resistance often originates from the contact resistance at the electrodes and from the contact resistance between metal and semiconductor. The conventional contact methods and materials are as follows: the semiconductor layer (P—Si) is in contact with the source/drain electrode (Ti/Al/Ti) as a metal-semiconductor contact with a large resistance, and the anode (ITO/Ag/ITO) and the source/drain electrode (Ti/Al/Ti) contact requires a metal annealing process with a corresponding contact resistance. In addition, the indium-tin oxide (ITO) film layer above the anode amorphous, which causes problems of low light transmittance and large electric resistance. Moreover, photons and electric energy in the ITO film layer are converted into heat energy. The lifetime of the organic emitting layer in the OLED display is short, and the life expectancy of the OLED display is drastically reduced in high temperature environments.

In view of this, there is a need to improve the existing OLED display panel to overcome the foregoing problems.

### SUMMARY OF INVENTION

It is one object of the present invention to provide a display panel and a manufacturing method thereof, which form a film by integrating an anode and a drain electrode to reduce the contact resistance between the anode and the drain electrode, thereby leaving out metal annealing. Moreover, the anode is made of zinc oxide, which is superior to ITO in resistance and light transmittance and is easy to be subsequently etched, thereby reducing the turn-on resistance of the display panel and increasing light reflection by the anode.

According to one aspect of the present invention, a display panel is provided, which includes: an array substrate provided with a plurality of thin-film transistors disposed therein; a planarization layer disposed on the array substrate; and a composite electrode disposed on the planarization layer and in contact with a semiconductor layer of each of the thin-film transistors through a via, wherein: the via includes a through hole penetrating the planarization layer and a drain hole communicating with the through hole, and the through hole and the drain hole are integrally formed; a portion of the composite electrode in contact with the semiconductor layer is made of a semiconductor material; and a metal layer and a superposed layer are stackedly disposed on the portion of the composite electrode in contact with the semiconductor layer, the superposed layer is made of zinc oxide and the metal layer is made of silver.

According to one aspect of the present invention, a display panel is provided, which includes: an array substrate provided with a plurality of thin-film transistors disposed therein; a planarization layer disposed on the array substrate; and a composite electrode disposed on the planarization layer and in contact with a semiconductor layer of each of the thin-film transistors through a via, wherein the via includes a through hole penetrating the planarization layer and a drain hole communicating with the through hole, and the through hole and the drain hole are integrally formed.

In one embodiment of the present invention, a portion of the composite electrode in contact with the semiconductor layer is made of a semiconductor material.

In one embodiment of the present invention, a metal layer and a superposed layer are stackedly disposed on a portion of the composite electrode in contact with the semiconductor layer.

In one embodiment of the present invention, the superposed layer is made of zinc oxide.

In one embodiment of the present invention, the metal layer is made of silver.

According to another aspect of the present invention, the present invention provides a manufacturing method of the display panel described above. The method includes the following steps: providing the array substrate with the plurality of thin-film transistors disposed therein; providing the planarization layer by coating on the thin-film transistors, and patterning the planarization layer to obtain the via including the through hole penetrating the planarization layer and the drain hole communicating with the through hole, the through hole and the drain hole being integrally formed; and forming the composite electrode on the planarization layer and in contact with the semiconductor layer of each of the thin-film transistors through the via.

In one embodiment of the present invention, a portion of the composite electrode in contact with the semiconductor layer is made of a semiconductor material.

In one embodiment of the present invention, a metal layer and a superposed layer are stackedly disposed on a portion of the composite electrode in contact with the semiconductor layer.

In one embodiment of the present invention, the superposed layer is made of zinc oxide.

In one embodiment of the present invention, the metal layer is made of silver.

One advantage of the present invention is that, in the OLED display panel of the present invention, the contact resistance between the anode and the drain electrode is reduced by forming the anode and the drain electrode into one, thereby skipping the metal annealing process. Moreover, a film layer formed of boron-doped zinc oxide is provided below the anode film layer to avoid a metal-semiconductor contact between the anode and the semiconductor layer. Above the anode film layer is provided a transparent polycrystalline zinc oxide film layer doped with porous boron, which has the characteristics of easy etching, high transmittance, low electrical resistance, and strong ability of upward hole transportation, thereby reducing the turn-on resistance of the display panel and increasing light reflection by the anode.

### DESCRIPTION OF DRAWINGS

In order to more clearly illustrate the embodiments or the technical solutions in the prior art, the drawings used in the embodiments or the prior art description will be briefly described below. Obviously, the drawings in the following description are only some implementations of the present invention. For example, other drawings may be obtained, without creative efforts, by those of ordinary skill in the art in light of the inventive work.

FIG. 1 is a schematic structural view of a conventional OLED display panel;

FIG. 2 is a schematic diagram showing the principle of illumination of a conventional OLED;

FIG. 3 is a schematic structural view of a display panel according to one embodiment of the present invention;

FIG. 4 is a schematic structural view showing a composite electrode disposed in region A in FIG. 3;

FIG. 5 is a flow chart showing the steps of a manufacturing method of a display panel according to one embodiment of the present invention; and

FIG. 6A to FIG. 6G are schematic diagrams showing a process flow of a manufacturing method of a display panel according to one embodiment of the present invention.

### DETAILED DESCRIPTION OF PREFERRED EMBODIMENTS

With reference to the accompanying drawings, the technical solutions in the embodiments of the present application will be clearly and completely described in the following. It is apparent that the described embodiments are only a part, rather than all, of the embodiments of the present application. Based on the embodiments of the present application, any other embodiments obtained by a person skilled in the art without creative efforts still fall within the scope of the present application.

In the specification, the claims and the drawings of the present invention, the terms “first”, “second”, “third” and the like (if any) are used to distinguish similar objects, and not necessarily to describe a specific sequence or order. It should be understood that the objects as described are interchangeable under appropriate circumstances. Furthermore, the terms “including” and “having” as well as any of their deformations are intended to cover non-exclusive inclusions.

In this patent document, the drawings discussed below and the embodiments used to describe the principles of the disclosure of the present invention are not intended to limit the scope of the disclosure of the present invention. Those skilled in the art will understand that the principles of the present invention may be implemented in any suitably arranged system. Exemplary embodiments will be described in detail, examples of which are illustrated in the accompanying drawings. Furthermore, a terminal according to the exemplary embodiments will be described in detail with reference to the accompanying drawings. Like reference numerals in the drawings refer to like elements.

The term used in this specification are used merely to describe particular embodiments, and is not intended to show the concept of the present invention. Unless the context clearly dictates, otherwise the expressions used in singular forms encompass the plural expressions. In this patent specification, it should be understood that the terms such as “including”, “having”, “comprising” and the like are intended to specify the disclosed features, numbers, steps, actions, or possible combinations thereof existing in the specification, and are not intended to exclude the possibility of the presence or addition of one or more other features, numbers, steps, actions, or combinations thereof. Like reference numerals in the drawings refer to like parts.

Embodiments of the present invention provide a display panel and a manufacturing method thereof, as will be respectively described in details below.

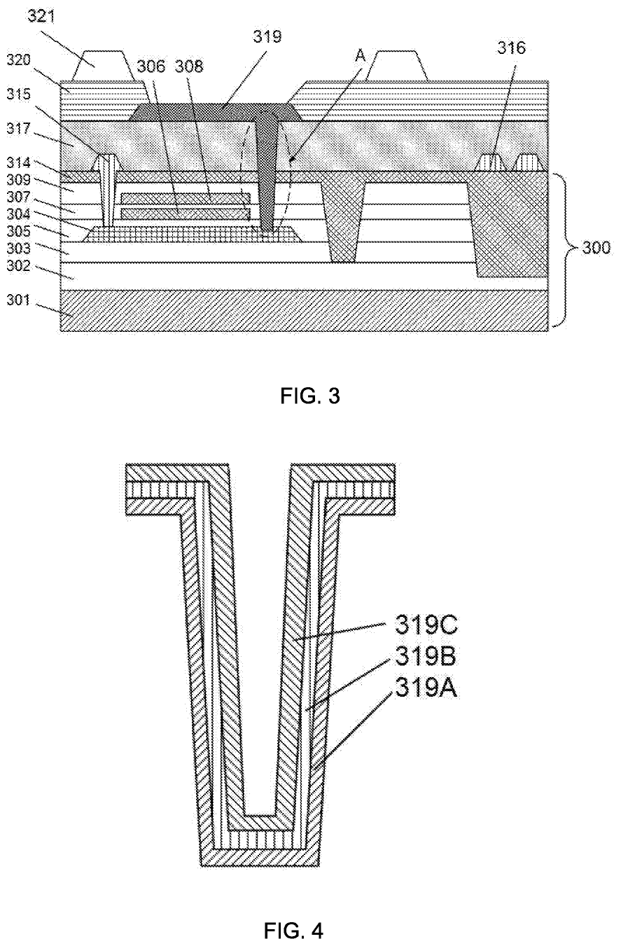

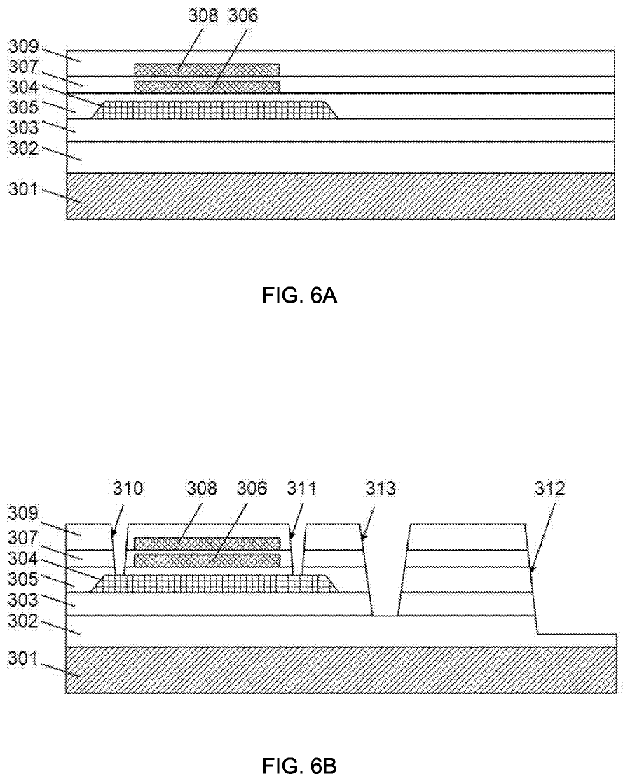

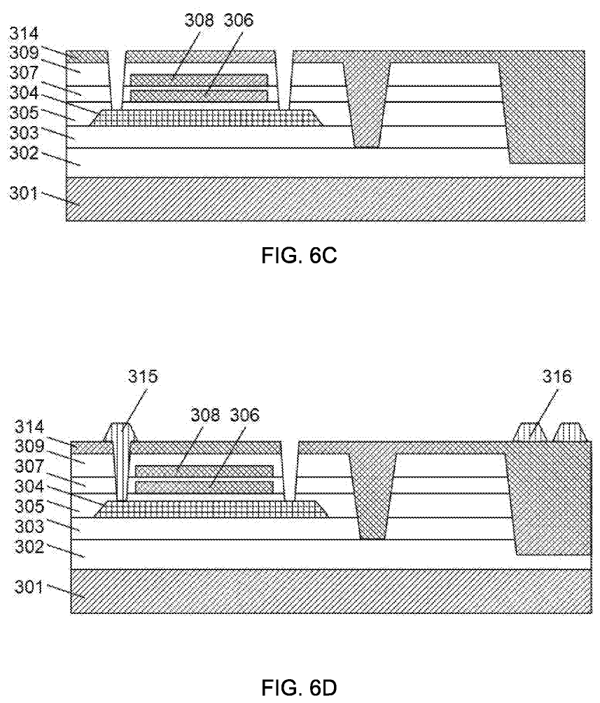

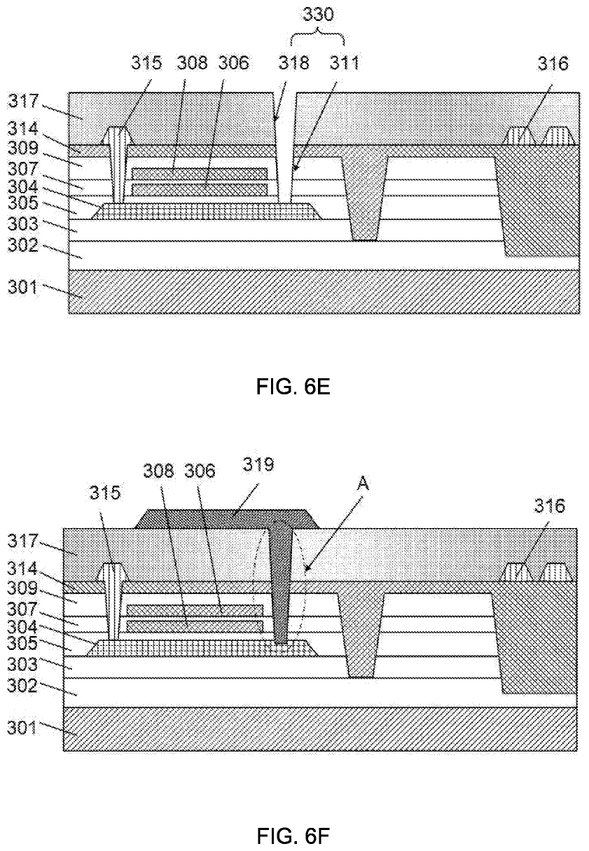

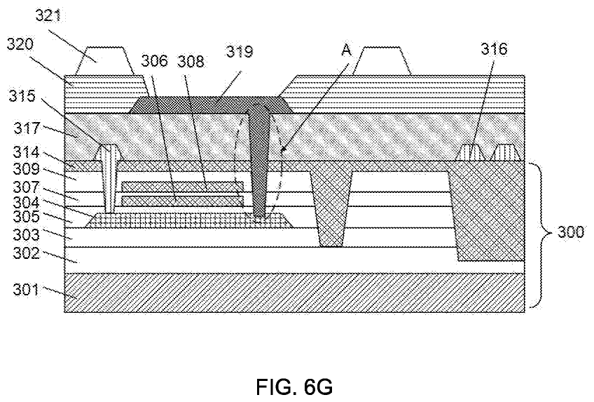

Referring to FIG. 3, the present invention provides a display panel, which includes: an array substrate 300 provided therein with a plurality of thin-film transistors arranged in an array; a planarization layer 317 disposed on the array substrate 300; and a composite electrode 319 disposed on the planarization layer 317 and in contact with a semiconductor layer 304 of the thin-film transistors through a via 330 (in, for example, FIG. 6E). The via 330 includes a through hole 318 penetrating the planarization layer 317 and a drain hole 311 communicating with the through hole 318, and the through hole 318 and the drain hole 311 are integrally formed.

More particularly, the structure of the thin-film transistors in the array substrate 300 is not limited, and may be a single-gate type, a double-gate type, a top-gate type, a bottom-gate type, etc. Taking the double-gate structure described in FIG. 3 for example, the array substrate 300 includes a flexible substrate 301, a barrier layer 302 overlying the flexible substrate 301, a buffer layer 303 overlying the barrier layer 302, a semiconductor layer 304 disposed on the buffer layer 303, a first gate insulating layer 305 overlying the buffer layer 303 and the semiconductor layer 304, a first gate 306 disposed above the semiconductor layer 304 and disposed on the first gate insulating layer 305, a second gate insulating layer 307 overlying the first gate insulating layer 305 and the first gate 306, a second gate 308 disposed above the first gate 306 and disposed on the second gate insulating layer 307, a first interlayer dielectric layer 309 overlying the second gate insulating layer 307 and the second gate 308, a second interlayer dielectric layer 314 overlying the first interlayer dielectric layer 309, and a source electrode 315 disposed on the second interlayer dielectric layer 314 and in contact with one side of the semiconductor layer 304 through the source hole 310 penetrating the second interlayer dielectric layer 314, the first interlayer dielectric layer 309, the second gate insulating layer 307, and the first gate insulating layer 305. The drain hole 311 penetrates the second interlayer dielectric layer 314, the first interlayer dielectric layer 309, the second gate insulating layer 307, and the first gate insulating layer 305 to expose another side of the semiconductor layer 304. Furthermore, the flexible substrate 301 may be made of a polymer material such as polyimide (PI) plastic, polyether ether ketone or transparent conductive polyester. In the present embodiment, a polyimide material (PI) material is used, which has advantages such as high temperature resistance, wide temperature range, non-obvious melting point, high insulation performance, stable dielectric constant, etc. The buffer layer 303 is made of silicon oxide, silicon nitride or a combination of the two. The semiconductor layer 304 includes, but is not limited to, amorphous silicon, low-temperature poly-silicon, metal oxide, and the like. The first interlayer dielectric layer 309 is made of silicon oxide, silicon nitride or a combination of the two. The second interlayer dielectric layer 314 is made of an organic photoresist. In addition, the planarization layer 317 is made of polyimide.

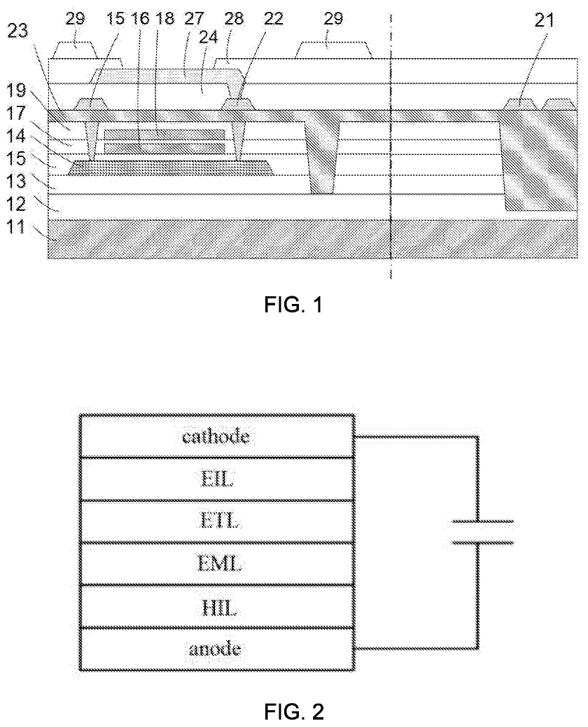

The composite electrode 319 integrates the anode and the drain electrode of the thin-film transistor (with reference to numeral 22 in FIG. 1) in one. In other words, the anode and the drain electrode are integrally formed, thereby reducing the contact resistance between the anode (with reference to numeral 27 in FIG. 1) and the drain electrode and skipping the metal annealing process. Referring to region A in FIG. 3 in conjunction with FIG. 4, the composite electrode 319 includes a portion (or referred to as a first composite electrode layer 319A) in contact with the semiconductor layer 304 of the thin-film transistors, a metal layer (or referred to as a second composite electrode layer 319B) and a superposed layer (or referred to as a third composite electrode layer 319C) stackedly disposed on the first composite electrode layer 319A.

The first composite electrode layer 319A is made of a semiconductor material, so that the metal-semiconductor contact between the anode and the semiconductor layer 304 can be avoided. In the present embodiment, the first composite electrode layer 319A is made of zinc oxide. In other embodiments, the first composite electrode layer 319A is made of a semiconductor material such as silicon, germanium or a combination thereof. Preferably, in order to enhance the conductivity of the first composite electrode layer 319A, the first composite electrode layer 319A may be made of a zinc oxide film layer doped with boron or phosphorus in the present embodiment. In this way, the first composite electrode layer 319A directly contacts the semiconductor layer 304 through the doped zinc oxide, significantly reducing the electrical resistance.

The metal layer (i.e., the second composite electrode layer 319B) is made of metal, preferably silver in the present embodiment due to its excellent light reflecting performance.

The superposed layer (i.e., the third composite electrode layer 319C) is made of zinc oxide. If the third composite electrode layer 319C is made of indium-tin oxide (ITO), the film layer is amorphous to facilitate the subsequent etching process. However, the density of an amorphous film layer is relatively low, the resistivity is relatively high, and the light transmittance is poor. If the film layer is polycrystalline, it cannot be etched. Therefore, in one embodiment of the present invention, the third composite electrode layer 319C is made of zinc oxide that has advantages such as high density, low resistivity, and high light transmittance and can be used as a polycrystalline film layer. Preferably, the third composite electrode layer 319C may be zinc oxide doped with porous boron. In this way, it is possible to provide a hole injection layer with stronger hole capability above the anode. In addition, zinc oxide is very capable of blocking metal diffusion from silver, aluminum, etc.

In addition, since the anode and the drain electrode are integrally formed as one single film and the portion of the composite electrode 319 in contact with the semiconductor layer 304 of the thin-film transistors is made of zinc oxide doped with boron or phosphorus, the turn-on resistance of the display panel can be significantly reduced to reduce energy consumption.

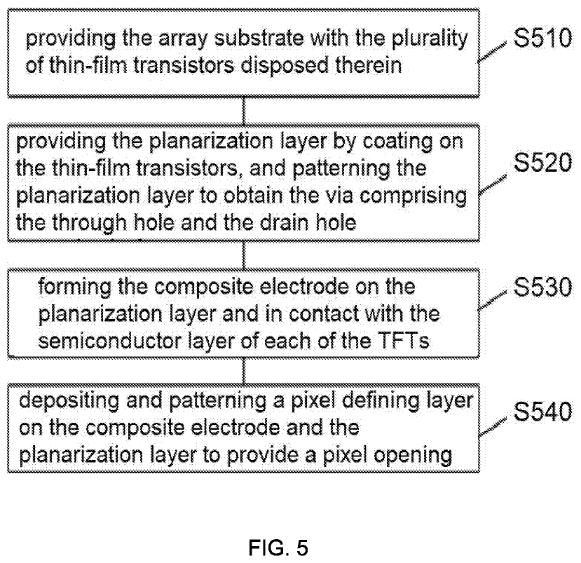

Referring to FIG. 5 and FIG. 6A to FIG. 6G, FIG. 5 is a flow chart showing the steps of a manufacturing method of a display panel according to one embodiment of the present invention, and FIG. 6A to FIG. 6G are schematic diagrams showing a process flow of a manufacturing method of a display panel according to one embodiment of the present invention.

The present invention provides a manufacturing method of the display panel described above. The method includes the following steps.

Referring to FIG. 6A, in Step S510, an array substrate is provided with a plurality of thin-film transistors disposed in the array substrate.

More particularly, the structure of the thin-film transistors in the array substrate 300 is not limited, and may be a single-gate type, a double-gate type, a top-gate type, a bottom-gate type, etc. Taking the double-gate structure described in FIG. 3 for example, the array substrate 300 includes a flexible substrate 301, a barrier layer 302 overlying the flexible substrate 301, a buffer layer 303 overlying the barrier layer 302, a semiconductor layer 304 disposed on the buffer layer 303, a first gate insulating layer 305 overlying the buffer layer 303 and the semiconductor layer 304, a first gate 306 disposed above the semiconductor layer 304 and disposed on the first gate insulating layer 305, a second gate insulating layer 307 overlying the first gate insulating layer 305 and the first gate 306, a second gate 308 disposed above the first gate 306 and disposed on the second gate insulating layer 307, a first interlayer dielectric layer 309 overlying the second gate insulating layer 307 and the second gate 308, a second interlayer dielectric layer 314 overlying the first interlayer dielectric layer 309, and a source electrode 315 disposed on the second interlayer dielectric layer 314 and in contact with one side of the semiconductor layer 304 through the source hole 310 penetrating the second interlayer dielectric layer 314, the first interlayer dielectric layer 309, the second gate insulating layer 307, and the first gate insulating layer 305. The drain hole 311 penetrates the second interlayer dielectric layer 314, the first interlayer dielectric layer 309, the second gate insulating layer 307, and the first gate insulating layer 305 to expose another side of the semiconductor layer 304. Furthermore, the flexible substrate 301 may be made of a polymer material such as polyimide (PI) plastic, polyether ether ketone or transparent conductive polyester. In the present embodiment, a polyimide material (PI) material is used, which has advantages such as high temperature resistance, wide temperature range, non-obvious melting point, high insulation performance, stable dielectric constant, etc. The buffer layer 303 is made of silicon oxide, silicon nitride or a combination of the two. The semiconductor layer 304 includes, but is not limited to, amorphous silicon, low-temperature poly-silicon, metal oxide, and the like. The first interlayer dielectric layer 309 is made of silicon oxide, silicon nitride or a combination of the two. The second interlayer dielectric layer 314 is made of an organic photoresist.

Referring to FIG. 6B, in the process of manufacturing the array substrate 300, the first interlayer dielectric layer 309, the second gate insulating layer 307, and the first gate insulating layer 305 are etched after the first interlayer dielectric layer 309 are formed so as to expose one side and the other side of the semiconductor layer 304, respectively, (i.e., forming an SD channel). Referring to FIG. 6C, the second interlayer dielectric layer 314 is formed on the first interlayer dielectric layer 309, and the second interlayer dielectric layer 314 is patterned by exposure to form a source hole 310 and a drain hole 311. If the display panel further includes a bending zone, a deep hole 312 is provided in the bending zone. A stress relief hole 313 is provided in a display area of the display panel. By providing the deep hole 312 and the stress relief hole 313 and filling materials in the subsequent steps, a good bending performance is achieved in the bending zone to increase the display area of the display panel, and a neutral surface in the bending zone is adjusted to enhance the bending performance.

Referring to FIG. 6D, after the holes are formed, a metal thin film is deposited on the second interlayer dielectric layer 314, and is etched to retain only the source electrode 315 formed by a portion of the metal thin film filled into the source hole 310 with the metal thin film filled into the drain hole 311 being removed to expose the drain hole 311. At the same time, a metal trace layer 316 is formed in the bending region.

Referring to FIG. 6E, in Step S520, the planarization layer is provided by coating on the thin-film transistors, and is patterned to obtain the via 330 including the through hole 318 penetrating the planarization layer 317 and the drain hole 311 communicating with the through hole 318. The through hole 318 and the drain hole 311 are integrally formed.

The array substrate 300 is coated with polyimide to form the planarization layer 317, and the planarization layer 317 is patterned by exposure to form a through hole 318 penetrating the planarization layer 317 and communicating with the drain hole 311 obtain the through hole 330 formed by the via 318 and the drain hole 311.

Referring to FIG. 6F, in Step S530, a composite electrode 319 is formed on the planarization layer 317. The composite electrode 319 is in contact with the semiconductor layer 304 of the thin-film transistors through the via 330.

More particularly, the composite electrode 319 integrates the anode and the drain electrode of the thin-film transistor in one. Therefore, the contact resistance between the anode and the drain electrode can be avoided, thereby skipping the metal annealing process. The composite electrode 319 includes a portion (or referred to as a first composite electrode layer 319A) in contact with the semiconductor layer 304 of the thin-film transistors, a metal layer (or referred to as a second composite electrode layer 319B) and a superposed layer (or referred to as a third composite electrode layer 319C) stackedly disposed on the first composite electrode layer 319A, as shown in FIG. 4.

The first composite electrode layer 319A is made of a semiconductor material, so that the metal-semiconductor contact between the anode and the semiconductor layer 304 can be avoided. In the present embodiment, the first composite electrode layer 319A is made of zinc oxide. In other embodiments, the first composite electrode layer 319A is made of a semiconductor material such as silicon, germanium or a combination thereof. Preferably, in order to enhance the conductivity of the first composite electrode layer 319A, the first composite electrode layer 319A may be made of a zinc oxide film layer doped with boron or phosphorus in the present embodiment. In this way, the first composite electrode layer 319A directly contacts the semiconductor layer 304 through the doped zinc oxide, significantly reducing the electrical resistance.

The metal layer (i.e., the second composite electrode layer 319B) is made of metal, preferably silver in the present embodiment due to its excellent light reflecting performance.

The superposed layer (i.e., the third composite electrode layer 319C) is made of zinc oxide. If the third composite electrode layer 319C is made of indium-tin oxide (ITO), the film layer is amorphous to facilitate the subsequent etching process. However, the density of an amorphous film layer is relatively low, the resistivity is relatively high, and the light transmittance is poor. If the film layer is polycrystalline, it cannot be etched. Therefore, in one embodiment of the present invention, the third composite electrode layer 319C is made of zinc oxide that has advantages such as high density, low resistivity, and high light transmittance and can be used as a polycrystalline film layer. Preferably, the third composite electrode layer 319C may be zinc oxide doped with porous boron. In this way, it is possible to provide a hole injection layer with stronger hole capability above the anode. In addition, zinc oxide is very capable of blocking metal diffusion from silver, aluminum, etc.

Since the anode and the drain electrode are integrally formed as one single film and the portion of the composite electrode 319 in contact with the semiconductor layer 304 of the thin-film transistors is made of zinc oxide doped with boron or phosphorus, the turn-on resistance of the display panel can be significantly reduced to reduce energy consumption. In the subsequent steps, the process can be simplified by skipping the metal annealing process for the purpose of reducing the contact resistance between the anode and the drain electrode of the thin-film transistor.

The method further includes Step S540 as shown in FIG. 6G, in which a pixel defining layer 320 is deposited on the composite electrode 319 and the planarization layer 317, and the pixel defining layer 320 is patterned by dry etching to provide a pixel opening surrounding the composite electrode 319. In addition, a spacer layer 321 is formed on the pixel defining layer 320.

One advantage of the present invention is that, in the OLED display panel of the present invention, the contact resistance between the anode and the drain electrode is reduced by forming the anode and the drain electrode into one, thereby skipping the metal annealing process. Moreover, a film layer formed of boron-doped zinc oxide is provided below the anode film layer to avoid the metal-semiconductor contact between the anode and the semiconductor layer 304. Above the anode film layer is provided a transparent polycrystalline zinc oxide film layer doped with porous boron, which has the characteristics of easy etching, high transmittance, low electrical resistance, and strong ability of upward hole transportation, thereby reducing the turn-on resistance of the display panel and increasing light reflection by the anode.

The above description is merely a preferred embodiment of the present invention, and it should be noted that those skilled in the art can make several improvements and modifications without departing from the principles of the present invention. These improvements and modifications should also be considered to fall within the scope of the present invention.

The subject matter of the present application can be manufactured and used in the industry with industrial applicability.

What is claimed is:

1. A display panel, comprising:
an array substrate provided with a plurality of thin-film transistors disposed therein;
a planarization layer disposed on the array substrate; and
a composite electrode disposed on the planarization layer and in contact with a semiconductor layer of each of the thin-film transistors through a via, wherein:
the via comprises a through hole penetrating the planarization layer and a drain hole communicating with the through hole, and the through hole and the drain hole are integrally formed,
a portion of the composite electrode in contact with the semiconductor layer is made of a semiconductor material, and
a metal layer and a superposed layer are stackedly disposed on the portion of the composite electrode in contact with the semiconductor layer, the superposed layer is made of zinc oxide and the metal layer is made of silver.

2. A display panel, comprising:
an array substrate provided with a plurality of thin-film transistors disposed therein;
a planarization layer disposed on the array substrate; and
a composite electrode disposed on the planarization layer and in contact with a semiconductor layer of each of the thin-film transistors through a via, wherein
the via comprises a through hole penetrating the planarization layer and a drain hole communicating with the through hole, and the through hole and the drain hole are integrally formed.

3. The display panel of claim 2, wherein a portion of the composite electrode in contact with the semiconductor layer is made of a semiconductor material.

4. The display panel of claim 2, wherein a metal layer and a superposed layer are stackedly disposed on a portion of the composite electrode in contact with the semiconductor layer.

5. The display panel of claim 4, wherein the superposed layer is made of zinc oxide.

6. The display panel of claim 4, wherein the metal layer is made of silver.

7. A manufacturing method of the display panel of claim 2, comprising the steps of:
providing the array substrate with the plurality of thin-film transistors disposed therein;
providing the planarization layer by coating on the thin-film transistors, and patterning the planarization layer to obtain the via comprising the through hole penetrating the planarization layer and the drain hole communicating with the through hole, the through hole and the drain hole being integrally formed; and
forming the composite electrode on the planarization layer and in contact with the semiconductor layer of each of the thin-film transistors through the via.

8. The manufacturing method of the display panel of claim 7, wherein a portion of the composite electrode in contact with the semiconductor layer is a semiconductor material.

9. The manufacturing method of the display panel of claim 7, wherein a metal layer and a superposed layer are stackedly disposed on a portion of the composite electrode in contact with the semiconductor layer.

10. The manufacturing method of the display panel of claim 7, wherein the superposed layer is made of zinc oxide.

11. The manufacturing method of the display panel of claim 7, wherein the metal layer is made of silver.
